(19) United States
(12) Patent Application Publication
(10) Pub. No.: US 2020/0219888 A1
(43) Pub. Date: Jul. 9, 2020

(54) METHOD FOR FABRICATING SEMICONDUCTOR DEVICE

(71) Applicant: XIA TAI XIN SEMICONDUCTOR (QING DAO) LTD., Qingdao (CN)

(72) Inventor: DONG-HOON KANG, Singapore (SG)

(21) Appl. No.: 16/692,731

(22) Filed: Nov. 22, 2019

Related U.S. Application Data
(60) Provisional application No. 62/778,924, filed on Dec. 13, 2018.

(51) Int. Cl. H01L 27/108; H01L 49/02; H01L 21/311

(52) U.S. Cl. CPC H01L 27/10852; H01L 21/31111; H01L 21/31116; H01L 28/91

(57) ABSTRACT

A method for fabricating a semiconductor device is provided. The method includes the actions of: providing on a substrate comprising an etch stop layer formed on the substrate; forming a stacked structure on the etch stop layer, the stacked structure including a lower pattern and at least one upper pattern, wherein each of the lower pattern and the at least one upper pattern includes a sacrificial layer and a support layer formed on the sacrificial layer; forming a hole penetrating the stacked structure and the etch stop layer; forming a lower conductive pattern in the hole; forming an opening penetrating the at least one upper pattern and the support layer of the lower pattern by a first etch process; and removing the sacrificial layers of the lower pattern and the at least one upper pattern by a second etch process.

### CROSS REFERENCE TO RELATED APPLICATION(S)

The present application claims the benefit of and priority to U.S. Provisional Application No. 62/778,924, filed on Dec. 13, 2018, the contents of which are incorporated herein by reference.

### FIELD

The present disclosure relates to semiconductor fabrication and more specifically to a capacitor having supporters and the fabricating method thereof.

### BACKGROUND

As the height of capacitors increases and the size of the memory array shrinks, the aspect ratio of the capacitors rises, weakening the stability of the capacitors. The collapse or twist of the capacitors may lead to poor yield rate.

### SUMMARY

The following presents a summary of examples of the present disclosure in order to provide a basic understanding of at least some of its examples. This summary is not an extensive overview of the present disclosure. It is not intended to identify key or critical elements of the present disclosure or to delineate the scope of the present disclosure. The following summary merely presents some concepts of the present disclosure in a general form as a prelude to the more detailed description provided below.

In one example, a method for fabricating a semiconductor device is provided. The method includes the actions of: providing on a substrate comprising an etch stop layer formed on the substrate; forming a stacked structure on the etch stop layer, the stacked structure including a lower pattern and at least one upper pattern, wherein each of the lower pattern and the at least one upper pattern includes a sacrificial layer and a support layer formed on the sacrificial layer; forming a hole penetrating the stacked structure and the etch stop layer; forming a lower conductive pattern in the hole; forming an opening penetrating the at least one upper pattern and the support layer of the lower pattern by a first etch process; and removing the sacrificial layers of the lower pattern and the at least one upper pattern by a second etch process.

In another example, a method for fabricating a semiconductor device is provided. The method includes the actions of: providing on a substrate comprising an etch stop layer formed on the substrate; forming a stacked structure on the etch stop layer, the stacked structure comprising a lower pattern and at least one upper pattern, wherein each of the lower pattern and the at least one upper pattern comprises a sacrificial layer and a support layer formed on the sacrificial layer; forming a hole penetrating the stacked structure and the etch stop layer; forming a lower conductive pattern in the hole; forming an opening penetrating the at least one upper pattern, the support layer of the lower pattern, and a portion of the sacrificial layer of the lower pattern by a first etch process; and removing the sacrificial layers of the lower pattern and the at least one upper pattern by a second etch process.

In yet another example, a semiconductor device is provided. The semiconductor device includes a substrate; a lower conductive pattern formed on the substrate. The lower conductive pattern has a V-shape structure with an outer sidewall. The semiconductor device further includes a first supporter connected to an upper area of the outer sidewall, a second supporter connected to a lower area of the outer sidewall, and a plurality of protrusions extending from the outer sidewall.

The details of one or more examples are set forth in the accompanying drawings and description below.

### BRIEF DESCRIPTION OF THE DRAWINGS

The accompanying drawings illustrate one or more implementations of the present disclosure and, together with the written description, explain the principles of the present disclosure. Wherever possible, the same reference numbers are used throughout the drawings referring to the same or like elements of an implementation.

FIG. 1A is a side cross-sectional view of a semiconductor device illustrating a method for fabricating a capacitor in the semiconductor device in a state before an etching process for forming openings is performed, in accordance with an implementation of the present disclosure.

FIG. 1B is a side cross-sectional view of the semiconductor device illustrating a method for fabricating a capacitor in the semiconductor device in a state that the openings are formed by the etching process, in accordance with an implementation of the present disclosure.

FIG. 1C is a side cross-sectional view of the semiconductor device illustrating a method for fabricating a capacitor in the semiconductor device in a state that a first conductive pattern is formed, in accordance with an implementation of the present disclosure.

FIG. 1D is a side cross-sectional view of the semiconductor device illustrating a method for fabricating a capacitor in the semiconductor device in a state that an opening is formed in a tapered pillar, in accordance with an implementation of the present disclosure.

FIG. 1E is a side cross-sectional view of the semiconductor device illustrating a method for fabricating a capacitor in the semiconductor device in a state that first and second sacrificial layers are removed, in accordance with an implementation of the present disclosure.

FIG. 1F is a side cross-sectional view of the semiconductor device illustrating a method for fabricating a capacitor in the semiconductor device in a state that a dielectric layer and a second conductive pattern are formed, in accordance with an implementation of the present disclosure.

FIG. 2A is a side cross-sectional view of a semiconductor device illustrating a depth of an opening in in the semiconductor device, in accordance with an implementation of the present disclosure.

FIG. 2B is a side cross-sectional view of the semiconductor device illustrating a depth of an opening in in the semiconductor device, in accordance with an implementation of the present disclosure.

FIG. 3 is a partial cross-sectional view of a semiconductor device illustrating a circuit element in the semiconductor device, in accordance with an implementation of the present disclosure.

### DETAILED DESCRIPTION

To facilitate an understanding of the principles and features of the various implementations of the present disclosure, various illustrative implementations are explained below. Although example implementations of the present disclosure are explained in detail, it is to be understood that other implementations are contemplated. Accordingly, it is not intended that the present disclosure is limited in its scope to the details of construction and arrangement of components set forth in the following description or illustrated in the drawings. The present disclosure is capable of other implementations and of being practiced or carried out in various ways.

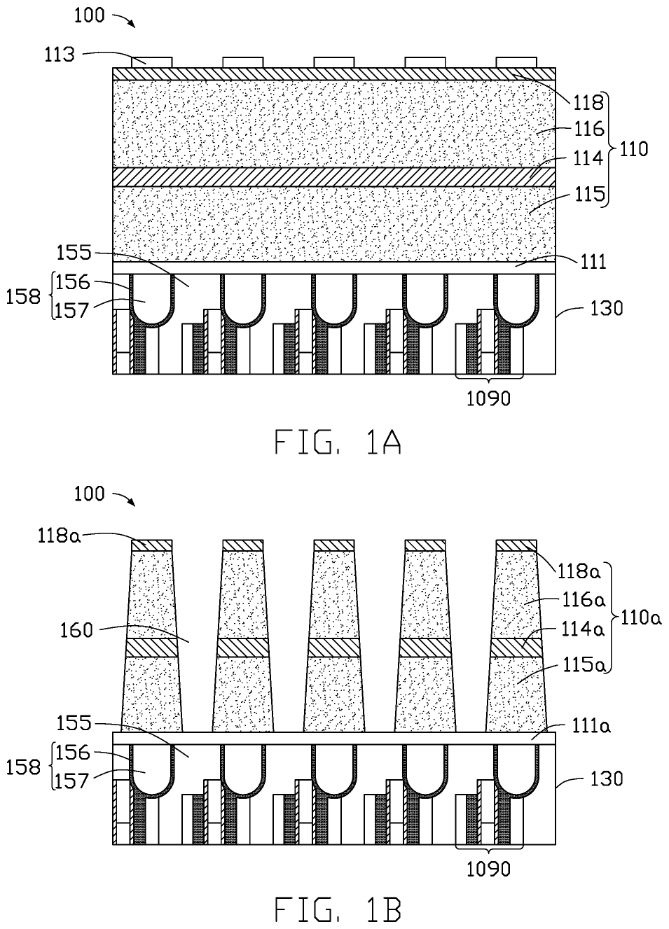

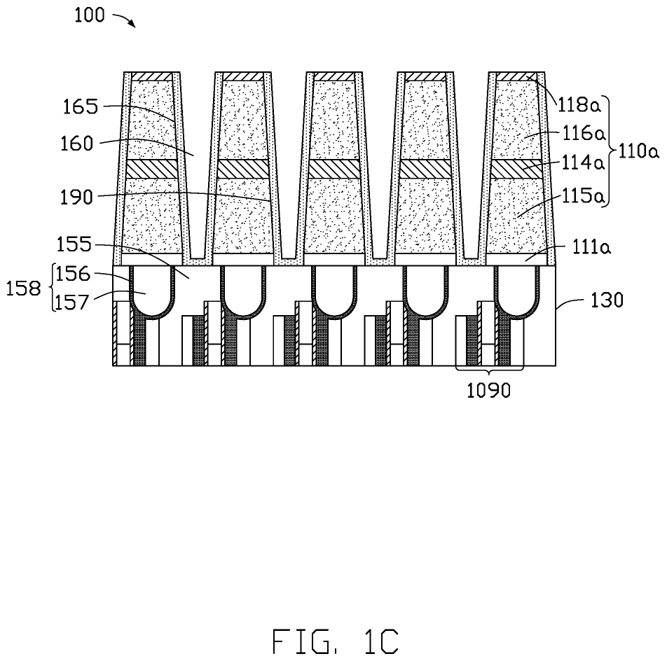

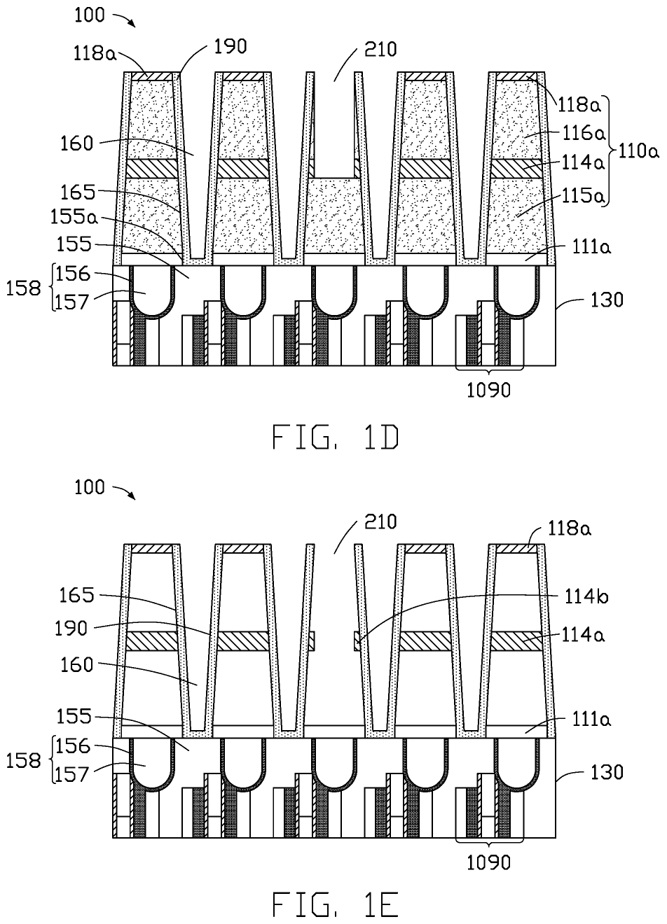

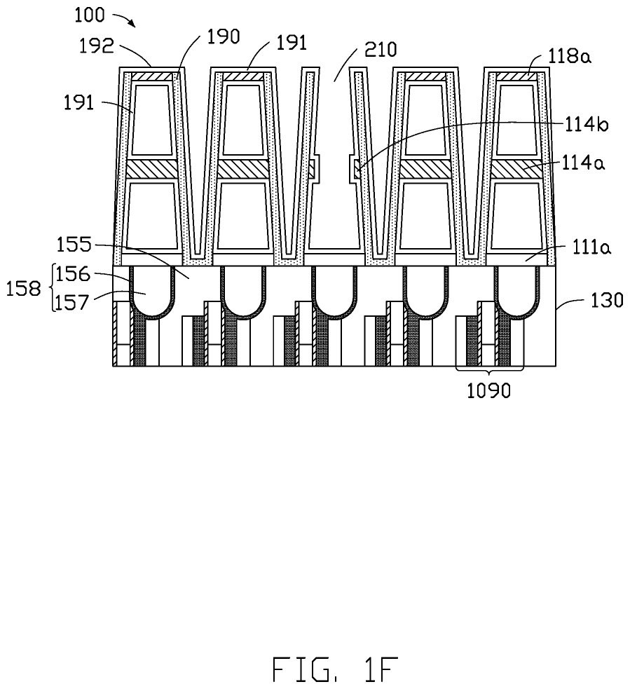

FIGS. 1A to 1F are side cross-sectional views illustrating an example method for fabricating a capacitor in a semiconductor device 100 in accordance with an implementation of the present disclosure. As shown in FIG. 1A, the semiconductor device 100 includes a substrate 130 and a preliminary pattern formed on the substrate 130. The semiconductor device 100 may be a dynamic random access memory (DRAM) device. The substrate 130 includes a landing pad 155 and a dielectric plug 158 having a first dielectric element 156 and a second dielectric element 157. The landing pad 155 may be formed of a metal material, such as tungsten, titanium, or tantalum. The first dielectric element 156 may be formed of a dielectric material, such as silicon nitride (SiN), by a chemical vapor deposition (CVD) process. The second dielectric element 157 may also be formed of a dielectric material, such as SiN, by an atomic layer deposition (ALD) process. In some implementations, the substrate 130 may be a silicon wafer. A circuit element 1090 including a gate structure, an impurity region, and/or a contact plug may be provided in the substrate 130.

The preliminary pattern includes an etch stop layer 111, a stacked structure 110 formed on the etch stop layer 111, and a plurality of mask patterns 113 formed over the stacked structure 110. The stacked structure 110 may be formed by sequentially stacking a first sacrificial layer 115, a first support layer 114, a second sacrificial layer 116, and a second support layer 118 using a deposition technique, such as ALD process, a plasma assisted atomic layer deposition (PAALD), a CVD process, a plasma enhanced chemical vapor deposition (PECVD) process, a low pressure chemical vapor deposition (LPCVD) process, a high density plasma chemical vapor deposition (HDP-CVD) process, a spin coating process, a sputtering process, or the like. Preferably, the stacked structure 110 has a thickness falling in the range of 1 to 1.3 microns (μm).

In some implementations, the etch stop layer 111 may include a material selected from SiN, silicon boron nitride (SiBN), silicon carbon nitride (SiCN), silicon carbide (SiC), silicon oxynitride (SiON), silicon oxycarbide (SiOC), or the like. The sacrificial layers 115, 116 may be formed of a silicon oxide-based material, such as silicon oxide (SiOx), plasma enhanced oxide (PEOX), boro silicate glass (BSG), phospho silicate glass (PSG), boro phospho silicate glass (BPSG), tetraethyl orthosilicate (TEOS), boro tetraethyl orthosilicate (BTEOS), phosphorous tetraethyl orthosilicate (PTEOS), or boro phospho tetraethyl orthosilicate (BPTEOS). The mask patterns 113 may be made of a combination of SiN and polysilicon. Alternatively, the mask patterns 113 may be made of a metal material.

As shown in FIG. 1B, an etching process is performed on the mask patterns 113 to form one or more openings 160 in the stacked structure 110 and expose the landing pad 155. For example, a dry etching process may be used. The resulting first openings 160 may each be a tapered trench. The upper width of each first opening 160 is wider than the lower width thereof. Accordingly, a plurality of tapered pillars 110a are formed on etch stop pads 111a. Each of the tapered pillars 110a includes a portion of the first sacrificial layer 115a, a portion of the first support layer 114a, a portion of the second sacrificial layer 116a, and a portion of the second support layer 118a. Each of the tapered pillars 110a protrudes upward and is in alignment with the dielectric plug 158.

As shown in FIG. 1C, a first conductive pattern 190 is formed in the opening 160 by a deposition process such as a CVD process or ALD process. The first conductive pattern 190 may serve as a lower electrode or a storage node of a capacitor of the DRAM device. The first conductive pattern 190 may be formed of a metallic material such as titanium nitride, titanium, tungsten, or the like. The first conductive pattern 190 may be electrically connected to the landing pad 155. In some implementations, the first conductive pattern 190 has a hollow circular cone structure.

As shown in FIG. 1D, an opening 210 is formed by an etch process to penetrate predetermined areas of the second support layer 118a, the second sacrificial layer 116a, and the first support layer 114a. The opening 210 may at least expose the first sacrificial layer 115a and the second sacrificial layer 116a. In some implementations, the etch process is a single-step dry etch process.

As shown in FIG. 1E, the first sacrificial layer 115a and the second sacrificial layer 116a are removed by a wet etch process. Preferably, the first sacrificial layer 115a and the second sacrificial layer 116a are etched through the opening 210 simultaneously.

In some implementations, the first conductive pattern 190 has a V-shape structure having an inner sidewall and an outer sidewall 165. The second support layer 118a are connected to an upper area of the outer sidewall 165. The first support layer 114a are connected to a lower area of the outer sidewall 165. Some of the first support layer 114a are split into protrusions 114b when the opening 210 is formed. The protrusions 114b are extended from the outer sidewall 165.

As shown in FIG. 1F, a dielectric layer 191 and a second conductive pattern 192 are formed by a deposition process such as a CVD process or ALD process. For example, the dielectric layer 191 covers the etch stop pads 111a, the first support layer 114a, the protrusion 114b, the second support layer 118a, and the first conductive pattern 190. Subsequently, the second conductive pattern 192 covers the dielectric layer 191 to serve as an upper electrode.

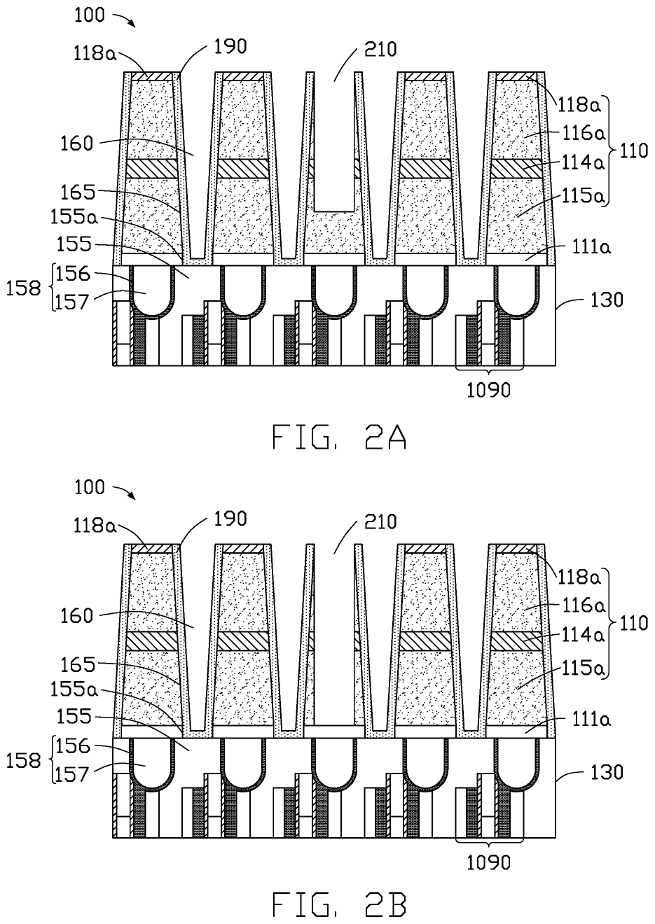

FIGS. 2A to 2B are side cross-sectional views illustrating depths of the opening 210 in accordance with an implementation of the present disclosure. FIGS. 2A and 2B include various features similar to those in FIGS. 1A through 1F. The descriptions of these features, which are designated with the same respective numerals, are omitted for brevity. As shown in FIG. 2A, the opening 210 is formed with a predetermined depth to form a recess in the first sacrificial layer 115a. As shown in FIG. 2B, the opening 210 is formed with a predetermined depth to expose the etch stop pads 111a. The depth of the opening 210 may affect the efficiency of the etch process for removing the first sacrificial layer 115a.

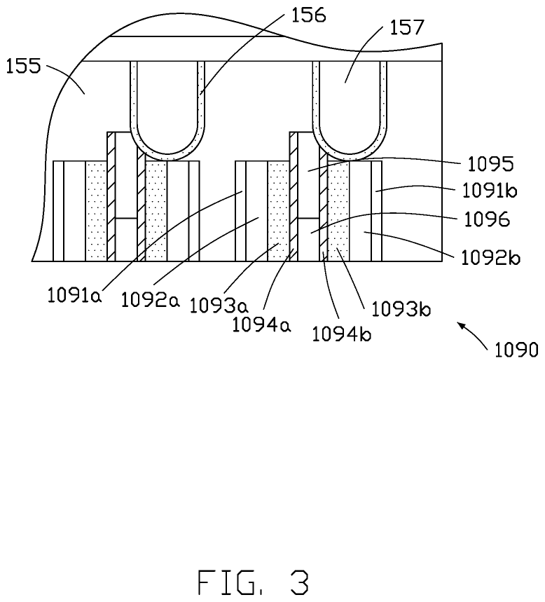

FIG. 3 is a cross-sectional view illustrating the circuit element 1090 in the semiconductor device 100. The circuit element 1090 may include first dielectric layers 1091a, 1091b, outer spacers 1092a, 1092b, second dielectric layers 1093a, 1093b, inner spacers 1094a, 1094b, a mask 1095, and a gate line 1096. In some implementations, the first dielectric layers 1091a, 1091b, the outer spacers 1092a, 1092b, the inner spacers 1094a, 1094b, and the mask 1095 may be made of material selected from SiN, SiBN, SiCN, SiC, SiON, and SiOC. The second dielectric layer 1093 may be made of silicon oxide-based material, such as SiOx, PEOX, BSG, PSG, BPSG, TEOS, BTEOS, PTEOS, and BPTEOS. The space filled by the second dielectric layers 1093a, 1093b may be air-gaps when the second dielectric layers 1093a, 109b are removed. The gate line 1096 may be made of a metal material, such as tungsten, titanium, or tantalum.

The terminology used herein is for the purpose of describing particular implementations only and is not intended to be limiting of implementations of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to implementations of the present disclosure in the form disclosed. Many modifications and variations will be apparent to those of ordinary skill in the art without departing from the scope and spirit of implementations of the present disclosure. The implementation was chosen and described in order to best explain the principles of implementations of the present disclosure and the practical application, and to enable others of ordinary skill in the art to understand implementations of the present disclosure for various implementations with various modifications as are suited to the particular use contemplated.

Although specific implementations have been illustrated and described herein, those of ordinary skill in the art appreciate that any arrangement which is calculated to achieve the same purpose may be substituted for the specific implementations shown and that implementations of the present disclosure have other applications in other environments. This present disclosure is intended to cover any adaptations or variations of the present disclosure. The following claims are in no way intended to limit the scope of implementations of the present disclosure to the specific implementations described herein.

Various examples have been described. These and other examples are within the scope of the following claims.

What is claimed is:

1. A method for fabricating a semiconductor device, the method comprising:
providing on a substrate comprising an etch stop layer formed on the substrate;
forming a stacked structure on the etch stop layer, the stacked structure including a lower pattern and at least one upper pattern, wherein each of the lower pattern and the at least one upper pattern includes a sacrificial layer and a support layer formed on the sacrificial layer;
forming a hole penetrating the stacked structure and the etch stop layer;
forming a lower conductive pattern in the hole;
forming an opening penetrating the at least one upper pattern and the support layer of the lower pattern by a first etch process; and
removing the sacrificial layers of the lower pattern and the at least one upper pattern by a second etch process.

2. The method of claim 1, wherein the first etch process is a single-step dry etch process.

3. The method of claim 1, wherein the first etch process is an inductively coupled plasma (ICP) reactive ion etching (RIE) process.

4. The method of claim 1, wherein the second etch process is a wet etch process.

5. The method of claim 4, wherein the sacrificial layers of the lower pattern and the at least one upper pattern are removed simultaneously by the wet etch process.

6. The method of claim 1, wherein the etch stop layer comprises a material selected from silicon nitride (SiN), silicon boron nitride (SiBN), silicon carbon nitride (SiCN), silicon carbide (SiC), silicon oxynitride (SiON), and silicon oxycarbide (SiOC).

7. The method of claim 1, wherein the sacrificial layer comprises a silicon oxide-based material selected from silicon oxide (SiOx), plasma enhanced oxide (PEOX), boro silicate glass (BSG), phospho silicate glass (PSG), boro phospho silicate glass (BPSG), tetraethyl orthosilicate (TEOS), boro tetraethyl orthosilicate (BTEOS), phosphorous tetraethyl orthosilicate (PTEOS), and boro phospho tetraethyl orthosilicate (BPTEOS).

8. The method of claim 1, wherein the support layer comprises silicon nitride (SiN) or silicon carbon nitride (SiCN).

9. The method of claim 1, wherein the lower conductive pattern comprises a metal material selected from titanium nitride (TiN), titanium (Ti), and tungsten (W).

10. The method of claim 1, wherein the lower conductive pattern has a hollow circular cone structure.

11. The method of claim 1, further comprising:
forming a dielectric pattern at least covering the lower conductive pattern, the support layers, and the etch stop layer; and
forming an upper conductive pattern covering the dielectric pattern.

12. A method for fabricating a semiconductor device, the method comprising:
providing on a substrate comprising an etch stop layer formed on the substrate;
forming a stacked structure on the etch stop layer, the stacked structure comprising a lower pattern and at least one upper pattern, wherein each of the lower pattern and the at least one upper pattern comprises a sacrificial layer and a support layer formed on the sacrificial layer;
forming a hole penetrating the stacked structure and the etch stop layer;
forming a lower conductive pattern in the hole;
forming an opening penetrating the at least one upper pattern, the support layer of the lower pattern, and a portion of the sacrificial layer of the lower pattern by a first etch process; and
removing the sacrificial layers of the lower pattern and the at least one upper pattern by a second etch process.

13. The method of claim 12, wherein the lower conductive pattern is a lower electrode for a capacitor in a dynamic random access memory (DRAM).

14. The method of claim 12, wherein the first etch process is a single-step dry etch process.

15. The method of claim 12, wherein the sacrificial layers of the lower pattern and the at least one upper pattern are removed simultaneously by a wet etch process.

16. A semiconductor device comprising:
a substrate;
a lower conductive pattern formed on the substrate, wherein the lower conductive pattern has
a V-shape structure with an outer sidewall;
a first supporter connected to an upper area of the outer sidewall;
a second supporter connected to a lower area of the outer sidewall; and
a plurality of protrusions extending from the outer sidewall.

17. The semiconductor device of claim 16, further comprising:
an etch stop layer formed on the substrate;
a dielectric layer covering the etch stop layer, the lower conductive pattern, the first supporter, the second supporter, and the plurality of protrusions; and
an upper conductive pattern formed over the dielectric layer.

18. The semiconductor device of claim 16, further comprising a landing pad electrically connected to the lower conductive pattern.

19. The semiconductor device of claim 16, wherein each of the first supporter, the second supporter, and the plurality of protrusions comprises silicon nitride (SiN) or silicon carbon nitride (SiCN).

20. The semiconductor device of claim 16, wherein the plurality of protrusions are in alignment with the second supporter in a horizontal plane.
